(19) United States
(12) Patent Application Publication
(10) Pub. No.: US 2023/0106946 A1
(43) Pub. Date: Apr. 6, 2023

(54) METHOD FOR DETERMINING A MODEL ERROR IN A MATHEMATICAL MODEL OF AN ELECTRICAL ENERGY STORAGE UNIT

(71) Applicant: Robert Bosch GmbH, Stuttgart (DE)

(72) Inventors: Jens Becker, Benningen Am Neckar (DE); Joerg Poehler, Korntal-Muenchingen (DE); Shweta Vijay Pawar, Kolhapur, Maharashtra (IN)

(21) Appl. No.: 17/911,223

(22) PCT Filed: Mar. 10, 2021
(86) PCT No.: PCT/EP2021/056104

§ 371 Date: Sep. 13, 2022

(30) Foreign Application Priority Data
Mar. 13, 2020 (DE) 10 2020 203 245.9

(51) Int. Cl. G01R 31/367

(52) U.S. Cl. CPC G01R 31/367

(57) ABSTRACT

The invention relates to a method for determining a model error in a mathematical model of an electrical energy storage unit, which method comprises the following steps: a) providing a mathematical error model for determining the model error in the mathematical model, wherein the mathematical error model is provided in at least a two-part form, wherein a first model error of an open-circuit voltage curve of the mathematical model of the electrical energy storage unit is modelled by the first part of the error model, and a second model error of a voltage curve of the mathematical model is modelled on the basis of an electrical current by the second part of the error model; b) determining at least one current value, wherein the electrical current flows in the electrical energy storage unit; c) applying the determined current value to the mathematical error model as the input value for the mathematical error model; d) determining the model error of the mathematical model as an output value for the mathematical error model, wherein the model error is dependent on the at least two part-models.

### BACKGROUND OF THE INVENTION

The present invention is based on a method for determining a model error in a mathematical model of an electrical energy storage unit.

Over the course of the increasing electrification, in particular of vehicles, electrical energy storage units are gaining ever increasing importance. In this case, there are different levels of electrification. There is, for example, purely electric vehicles and vehicles with an internal combustion engine in which an electric motor only temporarily takes over the driving of the vehicle or assists the internal combustion engine. These different forms of electrification typically have different voltage levels and different configurations of the electrical energy storage units used.

In this case, for example, the state of charge of the electrical energy storage units (SOC value) should be determined as accurately as required for safe and consistent operation in order to avoid breakdown of a corresponding vehicle or abrupt shutdown of the vehicle.

Also, electric buses should not break down on the driving route owing to an inaccurate SOC value and therefore an inaccurate range determination. It is therefore important in particular to be able to determine the state of charge precisely.

Inaccuracies in the state of charge are reflected in a false range or a false operating duration. For safety reasons, these times or the range are calculated too low since the calculations do not always build on actually measured values but also on partially estimated values in order to avoid a breakdown or a cessation of operation. As a result, range or operating time is wasted or overdimensioning of the corresponding systems takes place in order to arrive at corresponding values even under very conservative conditions.

Usually, a corresponding state determination takes place in model-based fashion. In order to improve the accuracy in particular of the state-of-charge determination and further states which are dependent thereon, it is expedient to establish statements on a possible model accuracy, with the result that, for example, a small model error can be used to perform an accurate state establishment, and, in the case of a correspondingly larger model error, possibly correspondingly more conservative actions need to be taken.

The document US2018/0321324 A1 describes a method for estimating the state of charge of a battery.

The document CN106772094 A describes a method for estimating the state of charge of a battery.

### SUMMARY OF THE INVENTION

A method for determining a model error in a mathematical model of an electrical energy storage unit having the features of the independent patent claim is disclosed.

In this case, a mathematical error model for establishing the model error in the mathematical model is provided. The mathematical error model is provided in at least two-part form. In this case, a first model error of an open-circuit voltage characteristic of the mathematical model of the electrical energy storage unit is modeled by the first part of the error model, which can be considered to be a static submodel. A second model error of a voltage characteristic of the mathematical model is modeled on the basis of an electrical current by the second part of the error model, which can be considered to be a dynamic submodel.

Furthermore, at least one current value is established. In this case, the electrical current whose current value is being established flows in the electrical energy storage unit.

The at least one established current value is then applied to the mathematical error model as input value.

The model error of the mathematical model is then determined as output value of the mathematical error model, wherein the model error is dependent on the at least two submodels.

This method is advantageous since it enables statements on the instantaneous model accuracy and therefore on the accuracy of the model states. If a high level of accuracy is provided at that moment, this can be taken into consideration in the further-processing of model states in order to enable qualitatively improved operation. Furthermore, the knowledge of the model error can be used to dynamize previously static limit values, for example upper and lower voltage limits, i.e., to match them to the respective model state. Therefore, possibly more power and/or energy can be retrieved from the electrical energy storage unit.

The mathematical model and the mathematical error model can comprise, for example, differential equations or difference equations or algebraic equations. Furthermore, a data-based family of characteristics can also be part of the mathematical model.

The method can be computer-implemented, for example.

Expediently, the model error is determined by a summation of the two submodel errors of the two submodels. The corresponding submodel errors of the at least two submodels are therefore added in order to establish the total model error. This is advantageous since, therefore, static errors and dynamic errors are considered equally, and therefore an accurate mapping of the model error is possible.

Advantageously, the present state of charge of the electrical energy storage unit is established, for example via an integration of the current. This is advantageous when different error values for different states of charge are provided within the error model. For example, different model errors of the open-circuit voltage can be stored for different states of charge in the first part of the error model, which models the open-circuit voltage characteristic of the electrical energy storage unit. This is advantageous since, therefore, the error model produces more accurate error values.

Expediently, the mathematical model of the electrical energy storage unit is included by the mathematical error model. Therefore, the mathematical error model has the mathematical model as a constituent part. This is advantageous since access can therefore be made to model-internal states of the mathematical model, which simplifies the model structure of the mathematical error model and facilitates calculations or avoids duplication of work. Furthermore, states of the mathematical model, for example electrical voltages, can be compared easily with measured values, which enables simple determination of error factors. These error factors are then, for example, a constituent part of the mathematical error model, which ensures a simple structure and implementability for the error model.

Expediently, the second part of the mathematical error model is formed by at least one first-order or higher-order time-delay element, wherein the submodel error of the second part is formed by means of a weighting of the output of the at least one time-delay element. This is advantageous since, as a result, operations with a small time constant, for example in the seconds range, and also operations with a large time constant, for example in the minutes or hours range, can be modeled. Therefore, an accurate error model can be achieved.

Expediently, a modeling of an open-circuit voltage hysteresis is included by the first part of the error model. This is advantageous in order to model and therefore take into consideration inaccuracies in the modeling of the open-circuit voltage curve which usually result owing to mean value generation, for example when a mean open-circuit voltage curve is formed from discharge open-circuit voltage curve and charging open-circuit voltage curve.

Expediently, a temperature dependence is exhibited by the first part of the error model and/or by the second part of the error model. This is advantageous since, in particular at low temperatures, i.e., in particular below 0° C., the modeling inaccuracies of the mathematical model increase, and therefore the mathematical error model advantageously takes this into consideration in order to make reliable statements on the model error.

Furthermore, the subject matter of the disclosure is a computer program which is designed to implement all of the steps of the disclosed method. Therefore, the mentioned advantages can be realized.

Furthermore, the subject matter of the disclosure is a machine-readable storage medium, on which the computer program is stored. Therefore, the computer program can be processed and run easily.

Furthermore, the subject matter of the disclosure is a device for determining a model error in a mathematical model of an electrical energy storage unit which comprises at least one means, which is designed to implement the steps of the disclosed method. This is advantageous since simple use of the method is enabled. The at least one means can comprise, for example, a battery management control device or an electronic control unit. An electronic control unit can in particular be understood to mean an electronic control device which comprises, for example, a microcontroller and/or an application-specific hardware module, for example an ASIC, but likewise a personal computer or a programmable logic controller can fall under this umbrella.

Furthermore, the subject matter of the disclosure is an electrical energy storage system, which comprises an electrical energy storage unit and the disclosed device. An electrical energy storage unit can in particular be understood to mean an electrochemical battery cell and/or a battery module having at least one electrochemical battery cell and/or a battery pack having at least one battery module. For example, the electrical energy storage unit can be a lithium-based battery cell or a lithium-based battery module or a lithium-based battery pack. In particular, the electrical energy storage unit can be a lithium-ion battery cell or a lithium-ion battery module or a lithium-ion battery pack. Furthermore, the battery cell can be of the type lithium-polymer rechargeable battery, nickel-metal hydride rechargeable battery, lead-acid rechargeable battery, lithium-air rechargeable battery or lithium-sulfur rechargeable battery or quite generally a rechargeable battery having any desired electrochemical composition.

### BRIEF DESCRIPTION OF THE DRAWINGS

Advantageous embodiments of the invention are illustrated in the figures and explained in more detail in the description below.

In the drawings:

FIG. 1 shows a schematic illustration of a mathematical error model in a two-part form in accordance with one embodiment;

FIG. 2 shows a flow chart of the disclosed method in accordance with one embodiment; and

FIG. 3 shows a schematic illustration of the disclosed electrical energy storage system in accordance with one embodiment.

Identical reference symbols in all of the figures denote identical device components or identical method steps.

### DETAILED DESCRIPTION

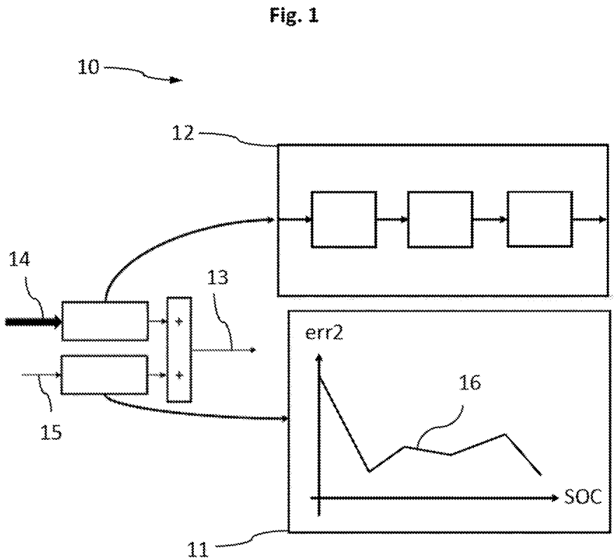

FIG. 1 shows a schematic illustration of a mathematical error model 10 in two-part form in accordance with one embodiment. In this case, a first model error of an open-circuit voltage characteristic of a mathematical model of an electrical energy storage unit is modeled by the first part 11 of the error model 10. The second part 12 of the error model 10 models a second model error of a voltage characteristic of the mathematical model of the electrical energy storage unit on the basis of an electrical current, i.e., when an electrical current or current value is applied to the mathematical model.

The second submodel 12 is in this case formed by a multiplication of various voltage values of the mathematical error model 10 by in each case one constant and by subsequent absolute value generation and summation of the resulting values. This is illustrated schematically by the three blocks in the second submodule 12. The corresponding voltage values are in this case represented symbolically by the arrow 14. This results in the first model error.

The first submodel 11 is in this case formed by a data-based family of characteristics 16 in which a corresponding model error err2 of the open-circuit voltage characteristic is assigned to each state-of-charge value SOC of an electrical energy storage unit. Depending on the present state of charge of the electrical energy storage unit, therefore, the corresponding model error err2 results, which is in this case higher, for example, in the case of lower state-of-charge values. The corresponding state-of-charge value is in this case represented symbolically by the arrow 15. This results in the second model error.

A model error 13 of the mathematical model of the electrical energy storage unit then results from the summation of the two model errors of the submodels 11, 12.

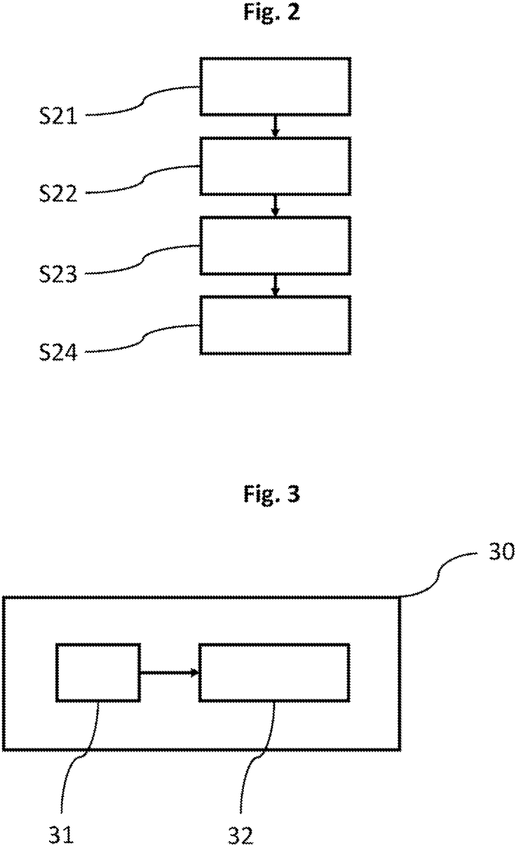

FIG. 2 shows a flowchart of the disclosed method for determining a model error in a mathematical model of an electrical energy storage unit in accordance with one embodiment.

In this case, in a first step S21, a mathematical error model is provided for establishing the model error of the mathematical model. The error model is present in at least two-part form. A first model error of an open-circuit voltage characteristic of the mathematical model is modeled by the first part of the error model. A second model error of a voltage characteristic of the mathematical model is modeled on the basis of an electrical current by the second part of the error model.

In a second step S22, at least one current value is established, wherein the electrical current flows in the electrical energy storage unit. Therefore, the current actually flowing in the electrical energy storage unit is established in order to be able to use it correspondingly in the mathematical model.

In a third step S23, the established at least one current value is used as input value of the mathematical error model, and therefore said current value is applied to the mathematical error model in order to be able to perform a corresponding model evaluation.

In a fourth step S24, the model error of the mathematical model is determined as output value of the mathematical error model, wherein the model error is dependent on the at least two submodels.

FIG. 3 shows a schematic illustration of the disclosed electrical energy storage system 30 in accordance with one embodiment. In this case, the electrical energy storage system 30 comprises an electrical energy storage unit 31 and a device 32 for determining a model error in a mathematical model of the electrical energy storage unit 31. The device 32 can in this case establish, for example, the current which is flowing through the electrical energy storage unit 31.

1. A method for determining a model error (13) in a mathematical model of an electrical energy storage unit (31), the method comprising:
a) providing a mathematical error model (10) for establishing the model error in the mathematical model, wherein the mathematical error model (10) is provided at least in two-part form, wherein a first model error of an open-circuit voltage characteristic of the mathematical model of the electrical energy storage unit (31) is modeled by the first part (11) of the error model, and a second model error of a voltage characteristic of the mathematical model is modeled on the basis of an electrical current by the second part (12) of the error model;
b) establishing a current value, wherein the electrical current flows in the electrical energy storage unit (31);
c) applying the established current value to the mathematical error model (10) as input value of the mathematical error model (10); and
d) determining the model error (13) of the mathematical model as an output value of the mathematical error model, wherein the model error (13) is dependent on the at least two submodels (11, 12).

2. The method as claimed in claim 1, wherein the model error (13) is determined in step d) by a summation of the two submodel errors of the two submodels (11, 12).

3. The method as claimed in claim 1, wherein the mathematical model of the electrical energy storage unit (31) is included by the mathematical error model (10).

4. The method as claimed in claim 1, wherein the second part (12) of the mathematical error model (10) is formed by at least one first-order or higher-order time-delay element, wherein the submodel error of the second part (12) is formed by means of a weighting of the output of the at least one time-delay element.

5. The method as claimed in claim 1, wherein a modeling of an open-circuit voltage hysteresis is included by the first part (11) of the error model.

6. The method as claimed in claim 1, wherein a temperature dependence is exhibited by the first part (11) of the error model and/or by the second part (12) of the error model.

7. (canceled)

8. A non-transitory, computer-readable storage medium containing instructions that when executed on a computer cause the computer to determine a model error (13) in a mathematical model of an electrical energy storage unit (31), by:
a) providing a mathematical error model (10) for establishing the model error in the mathematical model, wherein the mathematical error model (10) is provided at least in two-part form, wherein a first model error of an open-circuit voltage characteristic of the mathematical model of the electrical energy storage unit (31) is modeled by the first part (11) of the error model, and a second model error of a voltage characteristic of the mathematical model is modeled on the basis of an electrical current by the second part (12) of the error model;
b) establishing a current value, wherein the electrical current flows in the electrical energy storage unit (31),
c) applying the established current value to the mathematical error model (10) as input value of the mathematical error model (10); and
d) determining the model error (13) of the mathematical model as an output value of the mathematical error model, wherein the model error (13) is dependent on the at least two submodels (11, 12).

9. A device (22) for determining a model error (13) in a mathematical model of an electrical energy storage unit (31), the device comprising a computer configured to:
a) provide a mathematical error model (10) for establishing the model error in the mathematical model, wherein the mathematical error model (10) is provided at least in two-part form, wherein a first model error of an open-circuit voltage characteristic of the mathematical model of the electrical energy storage unit (31) is modeled by the first part (11) of the error model, and a second model error of a voltage characteristic of the mathematical model is modeled on the basis of an electrical current by the second part (12) of the error model;
b) establish a current value, wherein the electrical current flows in the electrical energy storage unit (31);
c) apply the established current value to the mathematical error model (10) as input value of the mathematical error model (10); and
d) determine the model error (13) of the mathematical model as an output value of the mathematical error model, wherein the model error (13) is dependent on the at least two submodels (11, 12).

10. An electrical energy storage system (30), comprising an electrical energy storage unit (31) and a device (32) as claimed in claim 9.
